(19) United States
(12) Patent Application Publication
(10) Pub. No.: US 2007/0285082 A1
(43) Pub. Date: Dec. 13, 2007

(54) Lock Detecting Circuit, Lock Detecting Method

(75) Inventors: Syuji Kimura, Nitta-gun, Gunma (JP); Takashi Hashizume, Ora-gun, Gunma (JP)

Correspondence Address: SoCAL IP LAW GROUP LLP, 310 N. WESTLAKE BLVD. STE 120, WESTLAKE VILLAGE, CA, 91362, US

(73) Assignee: SANYO ELECTRIC CO., LTD., OSAKA (JP)

(21) Appl. No.: 10/598,519

(22) PCT Filed: Feb. 14, 2005
(86) PCT No.: PCT/JP05/02157

§ 371 Date: Jun. 7, 2007

(30) Foreign Application Priority Data
Mar. 2, 2004 (JP) 2004-057529

(51) Int. Cl. G01R 25/00

(52) U.S. Cl. 324/76.77

(57) ABSTRACT

A lock detecting circuit is disclosed that detects whether a PLL circuit is in a locked state based on a phase difference signal supplied from a phase comparator of the PLL circuit, the lock detecting circuit comprising a first circuit that outputs a control signal having one level when the phase difference signal does not indicate a generation of a phase difference, and the other level when the phase difference signal indicates a generation of a phase difference; a second circuit that latches the control signal; and a third circuit that outputs, for a predetermined second term, a lock detecting signal indicating that the PLL circuit is in a locked state, when the latched control signal indicates the one level for a predetermined first term.

### CROSS-REFERENCE TO RELATED APPLICATION

This application claims the benefit of priority to International Patent Application PCT/JP2005/02157, filed Feb. 14, 2005, of which full contents are incorporated herein by reference.

### BACKGROUND OF THE INVENTION

1. Technical Field

The present invention relates to a lock detecting circuit of a PLL and a lock detecting method of a PLL.

2. Description of the Related Art

FIG. 6 shows the configuration of a conventional lock detecting circuit 600 including a PLL circuit (see, for example, Japanese Patent Application Laid-Open Publication No. 1994-112818).

The PLL circuit has a reference frequency divider 510, a voltage-controlled oscillator (hereinafter, VCO) 520, a comparative frequency divider 530, a phase comparator 540, a charge pump 550, and a low-pass filter (hereinafter, LPF) 560.

The reference frequency divider 510 is a frequency divider to divide the frequency of an oscillation clock signal created in a predetermined oscillating circuit and supply a reference signal fr to the phase comparator 540. In the VCO 520, an oscillation frequency is controlled corresponding to an applied voltage. An oscillation output fo of the VCO 520 is usually used as a system clock of an electronic apparatus that incorporates a PLL circuit.

The comparative frequency divider 530 is a frequency divider to divide the frequency of the oscillation output fo of the VCO 520 and supply a comparative signal fv to the phase comparator 540. The number of frequency dividing of the comparative frequency divider 530 is set corresponding to an oscillation frequency required as the oscillation output fo of the VCO 520.

The phase comparator 540 compares the phase of the reference signal fr with that of the comparative signal fv. When the phase of the reference signal fr is ahead of the phase of the comparative signal fv, the phase comparator 540 supplies a phase difference signal Φr corresponding to the phase difference to the charge pump 550. In contrast, when the phase of the reference signal fr is behind the phase of the comparative signal fv, the phase comparator 540 supplies a phase difference signal Φv corresponding to the phase difference to the charge pump 550.

The charge pump 550 supplies a voltage signal CP having a level corresponding to the phase difference signal Φr and the phase difference signal Φv to the LPF 560. The LPF 560 removes a high frequency component from the voltage signal CP and supplies to the VCO 520 a DC voltage Vr formed by converting the voltage signal CP into a DC voltage. As a result, the VCO 520 works to advance the phase of the comparative signal fv by increasing the oscillation frequency when a DC voltage Vr corresponding to the phase difference signal Φr is supplied. In contrast, the VCO 520 works to delay the phase of the comparative signal fv by decreasing the oscillation frequency when a DC voltage Vr corresponding to the phase difference signal Φv is supplied.

In this manner, by constructing a negative feedback circuit of the PLL, no phase difference is finally generated between the reference signal fr and the comparative signal fv. That is, the oscillation frequency of the oscillation output fo of the VCO 520 is in a state where the oscillation frequency is locked at a desired frequency.

The conventional lock detecting circuit 600 is a circuit to detect such a locked state, and consists of a NOR element 610, D flip flops (hereinafter, “FFs”) 620, 640, and 650, and an AND element 630. The configuration and the operation of the conventional lock detecting circuit 600 will be described referring to a circuit diagram of FIG. 6 and a timing charts of FIG. 7.

In FIG. 7, (a) shows a clock signal supplied to the FFs 620 and 640, (b) shows an output of the NOR element 610, (c) shows an output of the AND element 630, (d) shows a data input to the FF 650 at the final stage, and (e) shows an output of the FF 650 at the final stage.

The NOR element 610 outputs an H level when the phase difference signal Φr and the phase difference signal Φv are both at an L level, that is, when no phase difference is generated between the reference signal fr and the comparative signal fv (locked state) or when no phase comparison is executed, and outputs the L level in other cases (unlocked state) (see FIG. 7(b)).

For the FF 620, the output of the NOR element 610 is inputted to a data input terminal thereof, and a clock signal (see FIG. 7(a)) of which the frequency is divided in a predetermined manner in the reference frequency divider 510 is inputted to the clock input terminal thereof. Therefore, the FF 620 latches (holds) the output of the NOR element 610 in response to the rise of the inputted clock signal.

The AND element 630 outputs a logic product of the output of the NOR element 610 before and after the latching. That is, the AND element 630 inputs an H level into the data input terminal of the FF 640 at the next stage when the output of the NOR element 610 is at an H level that indicates the locked state and the latched level in the FF 620 is the H level (see FIG. 7(c)).

For the FF 640, the output of the AND element 630 is inputted into a data input terminal thereof and a clock signal that is the same as that inputted into the FF 620 is inputted into a clock input terminal thereof. Therefore, the FF 640 latches the output of the AND element 630 in response to the rise of the inputted clock signal. An inverted signal formed by inverting the latched output of the AND element 630 is inputted into a data input terminal of the FF 650 at the next stage (see FIG. 7(d)).

That is, the FF 640 outputs an H level as an inverting output when the term during which the output of the NOR element 610 indicates the H level is less than two cycles (see terms tc to te of FIG. 7(b)) and, in contrast, outputs an L level as an inverting output when the term is two cycles or more (see a term ti to of FIG. 7(b)).

For FF 650, the inverting output of the NOR element 610 is inputted into a clock input terminal thereof. Therefore, the FF 650 latches the inverting output of the FF 640 in response to the rise of the inputted inverting output of the NOR element 610. That is, the FF 650 latches the inverting output at the H level (see a time te of FIG. 7(e)) when the term during which the output of the NOR element 610 indicates the H level is less than two cycles (see terms tc to te of FIG. 7(b)) and, in contrast, latches the inverting output at the L level (see, a time to of FIG. 7(e)) when the term is two cycles or more (see a term ti to of FIG. 7(b)).

When the L level is latched by the FF 650, the PLL circuit is judged to be in the locked state. Therefore, in the locked state, a lock detecting signal LD outputted from the FF 650 is at the L level. In contrast, the PLL circuit is judged to be in an unlocked state when the H level is latched in the FF 650. Therefore, in the unlocked state, the lock detecting signal LD outputted from the FF 650 is at the H level.

After detecting the locked state (see the time to of FIG. 7 (e)), the lock detecting circuit shown in FIG. 6 maintains the lock detecting signal LD (L level) that indicates that the locked state is detected. When the PLL circuit is in the unlocked state thereafter, the locked state is remained detected though the PLL circuit is actually in the unlocked state as far as the lock detecting signal LD is reset at an appropriate timing. Therefore, a problem has arisen that the precision of the lock detection is degraded.

In FIG. 6, a case is considered where, after the locked state is switched to the unlocked state (see the time to of FIG. 7 (e)), as a result of generation of a jitter in the reference signal fr or the comparative signal fv due to the effect of a disturbance noise, etc., the operation of the phase comparator becomes unstable and the phase difference signal Φr and the phase difference signal Φv appear as whisker-like noises having a fine pulse width (for example, for the amount of “a cycle”). When the locked state is switched to the unlocked state, the outputs of the NOR element 610 and the AND element 630 are at the L level and the inverting output of the FF 640 is switched to the H level in response to the rise of the clock signal.

In this case, because the output of the NOR element 610 indicates the H level during the term that is less than two cycles (see a term tu to tw of FIG. 7 (e)), the inverting output of the FF 640 maintains the H level. The FF 650 latches the H level indicating the unlocked state (see a time tw of FIG. 7 (e)). That is, another problem is also arisen that the precision of the lock detection is degraded because the lock detecting signal LD is unintentionally reset due to the whisker-like noises, etc.

### SUMMARY OF THE INVENTION

In order to solve the above problems, according to a major aspect of the present invention there is provided a lock detecting circuit that detects whether a PLL circuit is in a locked state based on a phase difference signal supplied from a phase comparator of the PLL circuit, the lock detecting circuit comprising a first circuit that outputs a control signal having one level when the phase difference signal does not indicate a generation of a phase difference, and the other level when the phase difference signal indicates a generation of a phase difference; a second circuit that latches the control signal; and a third circuit that outputs, for a predetermined second term, a lock detecting signal indicating that the PLL circuit is in a locked state, when the latched control signal indicates the one level for a predetermined first term.

The other features of the present invention will become more apparent from the accompanying drawings and descriptions in this specification.

### BRIEF DESCRIPTION OF THE DRAWINGS

For more complete understanding of the present invention and the advantages thereof, the description below should be referenced in conjunction with the accompanying drawings in which:

FIG. 1 is a circuit diagram of a lock detecting circuit including a PLL circuit according to an embodiment of the present invention;

FIG. 2 is an explanatory timing chart of an operation of the PLL circuit according to an embodiment of the present invention;

FIG. 3 shows a circuit diagram of a counter, etc. according to an embodiment of the present invention;

FIG. 4 is an explanatory timing chart of an operation of the lock detecting circuit according to an embodiment of the present invention;

FIG. 5 is a circuit diagram of a decision-by-majority circuit or a weighting circuit according to an embodiment of the present invention;

FIG. 6 is a circuit diagram of the lock detecting circuit including a conventional PLL circuit; and

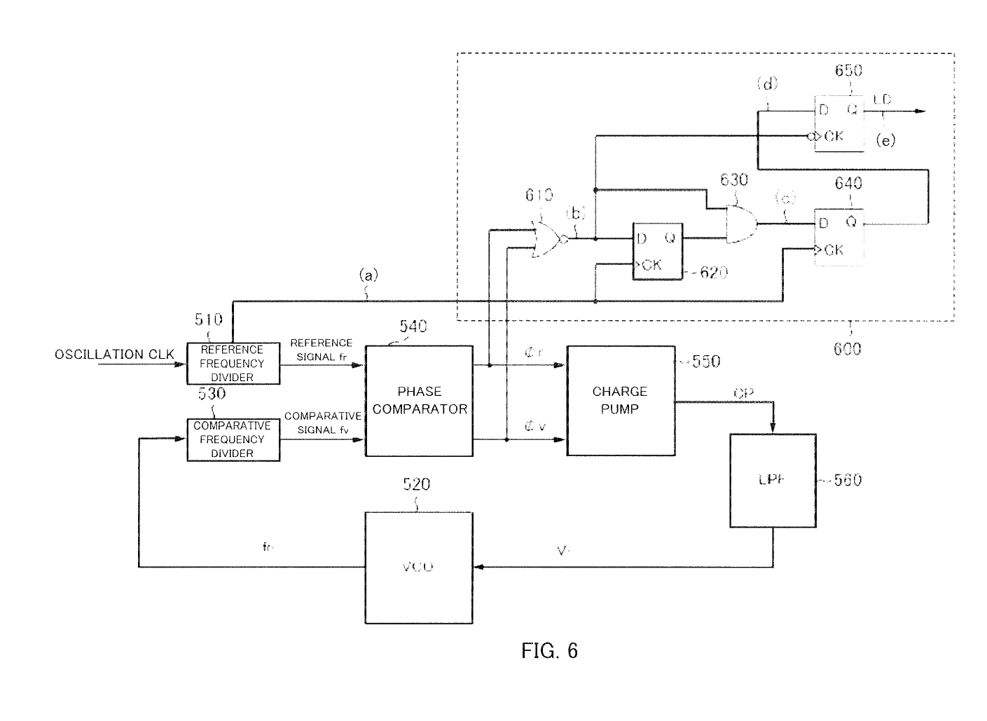

FIG. 7 is an explanatory timing chart of an operation of a conventional lock detecting circuit.

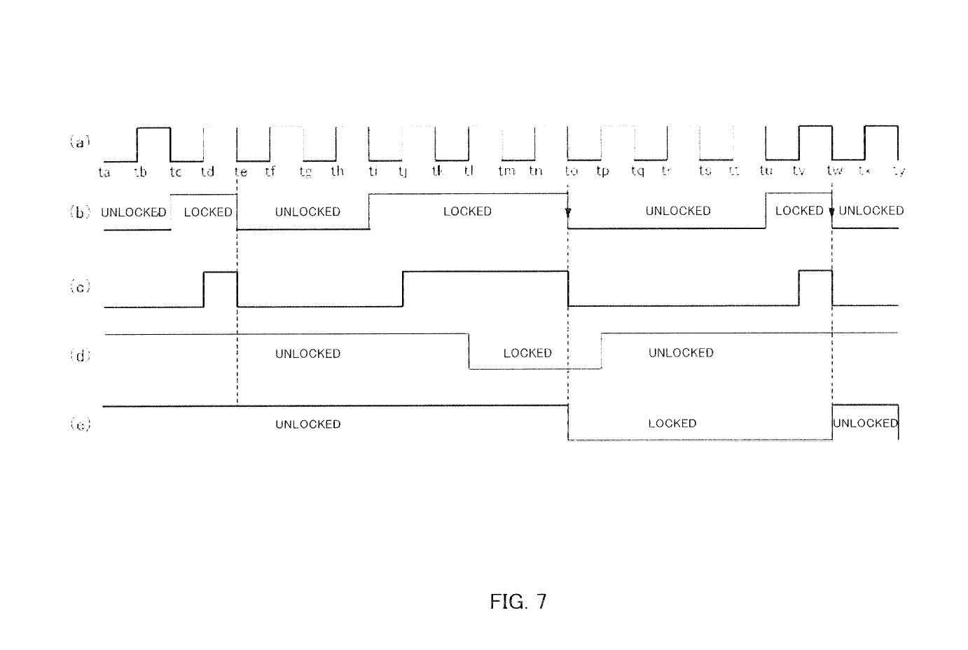

### DETAILED DESCRIPTION OF THE INVENTION

At least the items below will become clear from the descriptions in this specification and the accompanying drawings.

<Lock Detecting Circuit>

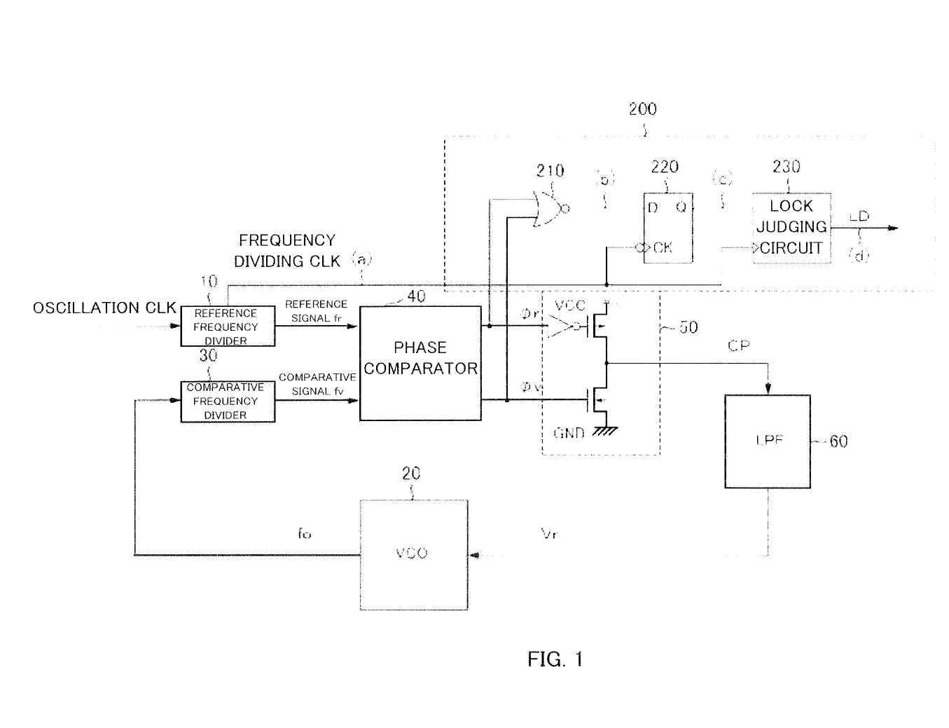

FIG. 1 is a circuit diagram of a lock detecting circuit including a PLL circuit according to an embodiment of the present invention. The lock detecting circuit of the embodiment is employed in all electronic apparatuses each of which incorporates a PLL circuit and needs lock judgment of the PLL such as a television, an FM receiver, a mobile communication apparatus. The lock detecting circuit of the embodiment may be implemented as an integrated circuit or a bipolar circuit that is separated from the PLL circuit or may be implemented as an integrated circuit integrated with the PLL circuit.

PLL Circuit

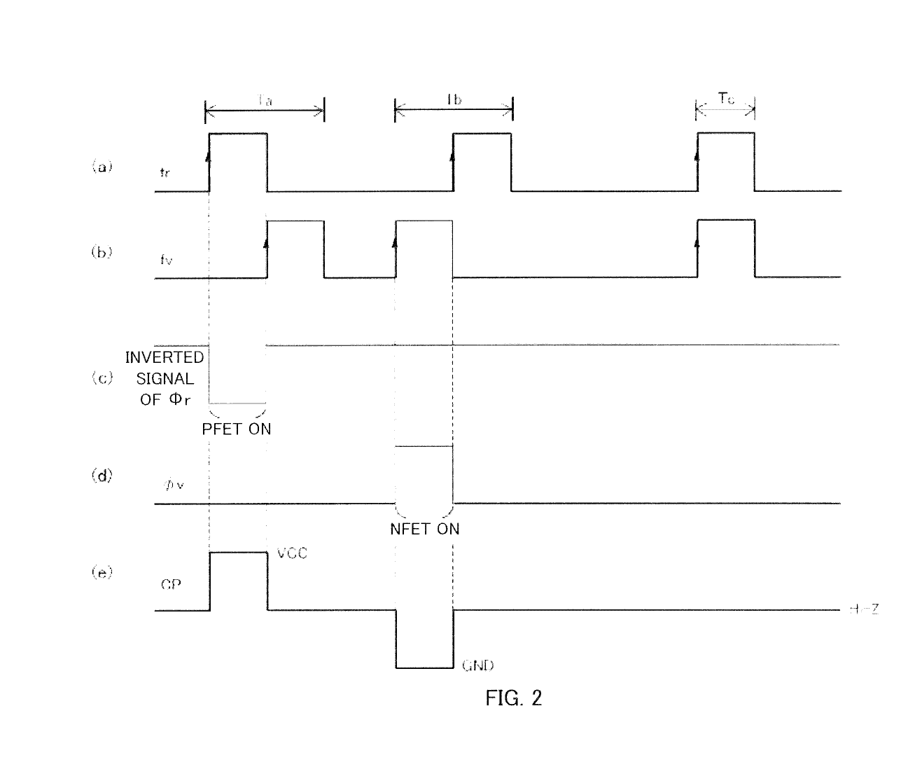

Referring to the circuit diagram of FIG. 1 and a timing chart of FIG. 2, a PLL circuit will be described that is the target of detecting locking by a lock detecting circuit 200 according to an embodiment of the present invention.

The PLL circuit has a reference frequency divider 10, a voltage-controlled oscillator (hereinafter, “VCO”) 20, a comparative frequency divider 30, a phase comparator 40, a charging pump 50, and a low-pass filter (hereinafter, “LPF”) 60. The PLL circuit is usually integrated except the LPF 60 and the LPF 60 is attached externally.

The reference frequency divider 10 is a frequency divider to divide the frequency of an oscillation clock signal (hereinafter, “oscillation CLK”) corresponding to a predetermined number of frequency dividing and supply a reference signal fr to the phase comparator 40. The oscillation CLK may be supplied by an automatic oscillation in an oscillation circuit such as a crystal oscillator and may be supplied by an external separatedly-excited oscillation.

In the VCO 20, an oscillation frequency is controlled corresponding to an applied voltage. A variable capacitance diode having a static capacitance that varies corresponding to an applied bias voltage is usually employed. An oscillation output fo of the VCO 20 is used as a reference clock signal of an electronic apparatus that incorporates a PLL circuit.

The comparative frequency divider 30 is a frequency divider to divide the frequency of the oscillation output fo of the VCO 20 corresponding to a predetermined number of frequency dividing and to supply a comparative signal fv to the phase comparator 40. The number of frequency dividing of the comparative frequency divider 30 is set corresponding to an oscillation frequency required as the oscillation output fo of the VCO 20. The comparative frequency divider 30 may be a fixed frequency divider for which the number of frequency dividing thereof is fixed or may be a programmable frequency divider to which the number of frequency dividing can be set arbitrarily.

The phase comparator 40 compares the phase of the reference signal fr with that of the comparative signal fv. When the phase of the reference signal fr is ahead of the phase of the comparative signal fv (see a term Ta of FIGS. 2(a) and 2(b)), the phase comparator 40 supplies a phase difference signal Φr corresponding to the phase difference (see the term Ta of the FIG. 2(c)) to the charging pump 50. In contrast, when the phase of the reference signal fr is behind the phase of the comparative signal fv (see a term Tb of FIGS. 2(a) and 2(b)), the phase comparator 40 supplies a phase difference signal Φv corresponding to the phase difference to the charging pump 50.

The charging pump 50 is, for example, configured by connecting in series a P-MOSFET and an N-MOSFET between a power source voltage VCO and a ground GND. An inverted signal of the phase difference signal Φr is supplied to a gate electrode of the P-MOSFET and the phase difference signal Φv is supplied to a gate electrode of the N-MOSFET. A voltage signal CP generated at a connecting point of the P-MOSFET and the N-MOSFET is supplied to the LPF 60.

That is, in the charging pump 50, when the phase difference signals Φr and Φv are both at an L level, the P-MOSFET and the N-MOSFET are both turned off and an output (the connecting point of the P-MOSFET and the N-MOSFET) shows a high impedance. When the phase difference signal Φr is at an H level and the phase difference signal Φv is at the L level, the P-MOSFET is turned on and the N-MOSFET is turned off and the charging pump 50 outputs a voltage signal CP corresponding to a power source voltage VCC (see the term Ta of FIG. 2(e)). When the phase difference signal Φr is at the L level and the phase difference signal Φv is at the H level, the P-MOSFET is turned off and the N-MOSFET is turned on and the charging pump 50 outputs a voltage signal CP corresponding to the ground GND (see the term Tb of FIG. 2(e)).

The LPF 60 removes a high frequency component from the voltage signal CP and supplies to the VCO 20 a DC voltage Vr formed by converting the voltage signal CP into a DC voltage. As a result, the VCO 20 works to increase the oscillation frequency to advance the phase of the comparative signal fv when a DC voltage Vr corresponding to the phase difference signal Φr is supplied. In contrast, the VCO 20 works to decrease the oscillation frequency to delay the phase of the comparative signal fv when the DC voltage Vr corresponding to the phase difference signal Φv is supplied.

By constructing a negative feedback PLL circuit, no phase difference is finally generated between the reference signal fr and the comparative signal fv. That is, the oscillation frequency of the oscillation output fo of the VCO 20 is in a state where the oscillation frequency is locked at a desired frequency.

Lock Detecting Circuit

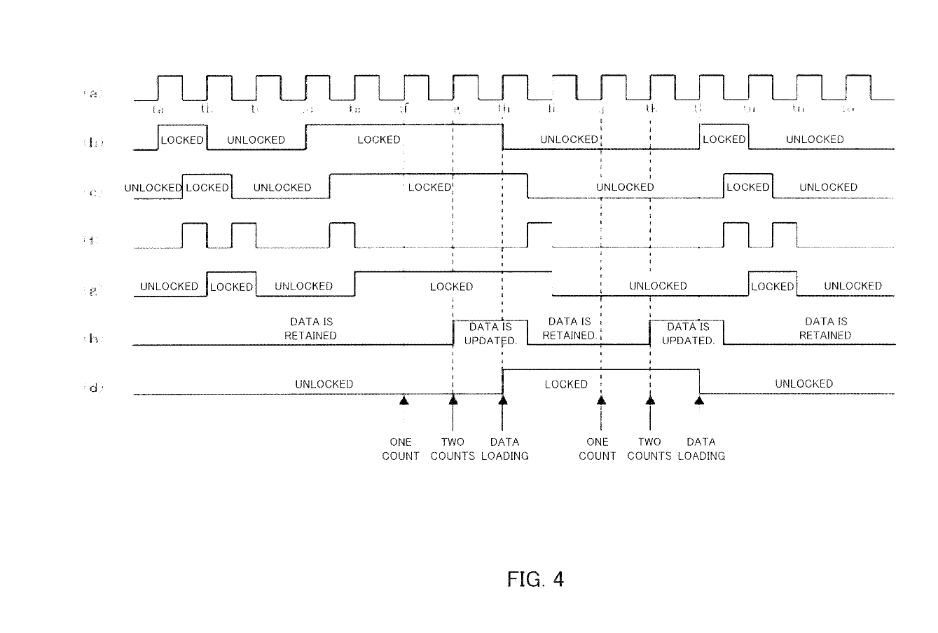

A lock detecting circuit 200 has a NOR element 210, a D flip flop (hereinafter, “FF”) 220, and a lock judging circuit 230. The configuration and the operation of the lock detecting circuit 200 will be described referring to FIG. 1 and a timing chart of FIG. 4. In FIG. 4, (a) shows the frequency dividing CLK described later to be supplied to the FF 220 and the lock judging circuit 230, (b) shows a control signal described later to be outputted from the NOR element 210, (c) shows an output of the FF 220, and (d) shows a lock detecting signal LD described later to be outputted from the lock judging circuit 230.

The NOR element 210 (“first circuit”) outputs a control signal at an H level (“one level”) when the phase difference signals Φr and Φv are both at an L level, that is, when no phase difference is generated between the reference signal fr and the comparative signal fv (locked state) or when no phase comparison is executed, and outputs a control signal at the L level (“the other level”) in other cases (unlocked state). Though the NOR element 210 is employed in the embodiment, the NOR element may be changed to a proper circuit element corresponding to the specification of the phase comparator 40.

For the FF 220 (“second circuit”), the control signal supplied from the NOR element 210 is inputted into a data input terminal thereof, and a frequency dividing clock signal (“frequency dividing CLK”) formed by dividing the frequency of the oscillation CLK in a predetermined manner in the reference frequency divider 10 is inputted being phase-inverted to the clock input terminal thereof. Therefore, the FF 220 latches the control signal supplied from the NOR element 210 in response to the fall of the inputted frequency dividing CLK.

For example, as shown in a term (ta to tb) of FIG. 4(b) in the locked state where no phase difference is generated between the reference signal fr and the comparative signal fv, the H level (“one level”) is latched for a term corresponding to the term (ta to tb) of FIG. 4(b) (see FIG. 4(c)). As shown in a term (tb to td) of FIG. 4(b), in the unlocked state, the L level (“the other level”) is latched for a term corresponding to the term (tb to td) of FIG. 4(b) (see FIG. 4(c)).

When the control signal latched in the FF 220 shows the H level for a desired first term, the lock judging circuit 230 (“third circuit”) outputs a lock detecting signal LD indicating that the lock state is detected, for the predetermined second term corresponding to a term during which the control signal latched in the FF 220 indicates the H level.

For example, a term until latch timings of FF 220 (the rises of the frequency dividing CLK) have generated for a plurality of times, that is, a plurality of cycles of the frequency dividing CLK is set as the first term for the lock judgment not to be executed based on the whisker-like noises latched in FF 220.

The second term may be the same as a term during which the control signal latched in the FF 220 shows the H level and, for example, may be a cycle (a pulse) of the frequency dividing CLK. When only a cycle of the frequency dividing CLK is outputted, on a predetermined receiving circuit side of the lock detecting signal LD, a latching circuit needs to be provided that latches the received lock detecting signal LD for only a term during which the control signal latched in the FF 220 shows the H level.

When the phase difference does not converge and is in an unstable state in the phase comparator 40 due to, for example, generation of a jitter in the reference signal fr or the comparative signal fv, fine phase difference signals Φr and Φv each having the pulse width at the H level (noises) are generated. At this time, the control signal that is the output of the NOR element 210 is at the L level and, as a result, the FF 220 may latch the L level. However, the lock judging circuit 230 does not execute wrong judgment of locking/unlocking based on the level of the control signal latched in the FF 220 for the cycle and, therefore, the precision of the lock detection is improved.

The lock detecting signal LD is outputted only for the second term. That is, the lock detecting signal LD is securely reset after the second term and, therefore, no lock detecting signal LD that does not reflect the actual state is outputted not as in the conventional case.

<Lock Detecting Circuit>

<<Counter Scheme>>

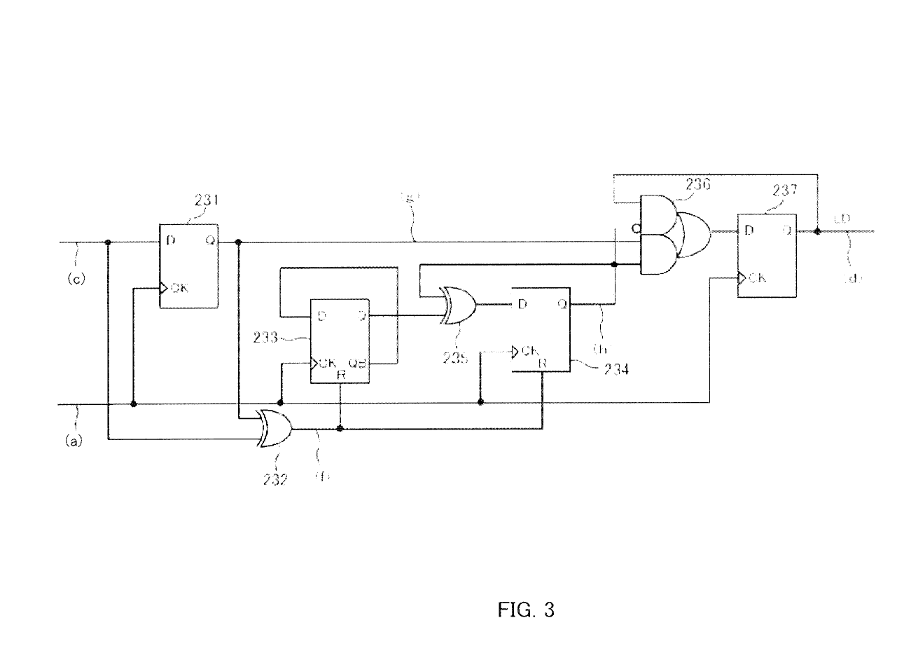

The configuration and the operation of the counter-scheme lock judging circuit 230 according to an embodiment of the present invention will be described referring to a circuit diagram of FIG. 3 and the timing chart of FIG. 4.

The counter-scheme lock judging circuit 230 measures a term during which the control signal latched in the FF 220 continuously indicates the H level and, when the length of the measured term exceeds the length of the predetermined first term, outputs the lock detecting signal LD for the second term during which the control signal latched in FF 220 indicates the H level. Setting the first term that is the basis of the lock judgment to be a proper term enables the judgment of locking/unlocking to be executed precisely and efficiently.

FIG. 3 is an example of the circuit configuration obtained when two cycles of the frequency dividing CLK are set as the first term. In FIG. 3, (a) denotes the frequency dividing CLK, (c) denotes the output of the FF 220, and (d) denotes the lock detecting signal LD.

The counter-scheme lock judging circuit 230 consists of FFs 231, 233, 234, and 237 that are synchronized by a common frequency dividing CLK, ExOR (exclusive OR) elements 232 and 235, and a gate element 236.

For the FF 231, the output of the FF 220 is inputted into a data input terminal thereof and the frequency dividing CLK is inputted into a clock input terminal thereof. Thereby, the FF 231 latches the output of the FF 220 in response to the rise of the frequency dividing CLK (see FIG. 4(g)).

The ExOR element 232 monitors the state of the input and the output of the FF 231, that is, the ExOR element 232 monitors switching between the locked and the unlocked states in the FF 231 and, when the states of the input and the output of the FF 231 are the same or different, outputs respectively the L or H level (see FIG. 4(f)). The timings of the state changes respectively at the input and the output of the FF 231 are different from each other by ½ cycle of the phase of the frequency dividing CLK and, therefore, the term during which the H level is outputted from the ExOR element 232 as a resetting signal is ½ cycle of the frequency dividing CLK. The output of the ExOR element 232 is used as a resetting signal (when the output is at H level) to reset the states of the FFs 233 and 234.

A logic circuit (233, 234, and 235) configured by coupling the FF 233, the ExOR 235, and the FF 234 outputs the H level when a time period corresponding to two cycles of the frequency dividing CLK have passed since the resetting signal has been cancelled after ½ cycle of the frequency dividing CLK has passed since the logic circuit has received the resetting signal. Thereafter, until the next resetting signal is received, the FF 234 outputs the H level or the L level (see FIG. 4(h)). When the next resetting signal has been received before the time period corresponding to two cycles of the frequency dividing CLK passes after the resetting signal has been cancelled, the FF 231 outputs no H level and maintains outputting the L level. That is, the logic circuit (233, 234, and 235) monitors whether the locked/unlocked state in the FF 231 continues for (½+2) cycles of the frequency dividing CLK.

For example, as shown in FIG. 4(h), at time tg after two cycles of the frequency dividing CLK have passed since the resetting signal has been cancelled at time te, the L level output is switched to the H level output. When the next resetting signal is inputted after ½ cycle of the frequency dividing CLK since time th, the H level output is switched to the original L level output.

Another logic circuit (236 and 237) configured by coupling the gate element 236 and the FF 237 maintains the previous state as an output of the FF 237 when the output of the FF 234 is the L level. When the output of the FF 234 is the H level, the FF 237 latches the output of the FF 231 at the rise of the frequency dividing CLK. When the H level is latched in the FF 237, the PLL circuit is judged to be in the locked state. Therefore, in the locked state, the lock detecting signal LD outputted from the FF 237 is at the H level. When the L level is latched in the FF 237, the PLL circuit is judged to be in the unlocked state. Therefore, in the unlocked state, the lock detecting signal LD outputted from the FF 237 is at the L level.

That is, when the locked/unlocked state in the FF 231 does not continue for the term of (½+2) cycles of the frequency dividing CLK, the logic circuit (236 and 237) maintains the level of the lock detecting signal LD. When the locked/unlocked state in the FF 231 continues for the length of a term exceeding (½+2) cycles of the frequency dividing CLK, the logic circuit (236 and 237) switches the level of the lock detecting signal LD to the level that indicates the continuing locked/unlocked state. The level of the switched lock detecting signal LD is maintained for a term during which the locked/unlocked state indicated by the level continues.

Therefore, for example, when the whisker-like noises are generated in the phase comparator 40 or when the locked/unlocked state continues for a short term, no wrong judgment of the locked/unlocked state is executed because the level of the lock detecting signal LD does not vary. Therefore, the precision of detecting locking (or unlocking) is improved.

In the embodiment described above, it is preferable to use a signal formed by inverting the phase of the clock signal used for latching as the clock signal used in the counter-scheme lock judging circuit 230 because, when the whisker-like noises are latched in the FF 220, the noise can be prevented from propagating to the interior of the lock judging circuit 230 at the timing of the latching.

In the embodiment described above, it is preferable that the clock signal used in the counter-scheme lock judging circuit 230 and the clock signal used for latching in the FF 220 are created from an identical clock source because, as described above, this is to always coincide the term during which the lock detecting signal LD is at the H level and the term during which the control signal latched in the FF 220 is at the H level.

<<Decision-by-Majority Scheme>>

The lock judging circuit 230 according to an embodiment of the present invention may employ a decision-by-majority scheme. According to the decision-by-majority scheme, a state indicated by the longer one of a term during which the locked state is indicated and a term during which the unlocked state is indicated in a predetermined judgment term is outputted as the lock detecting signal LD.

In FIG. 1, for example, the decision-by-majority-scheme lock judging circuit 230 is configured to output the lock detecting signal LD at the H level when a length of the term during which the control signal latched in the FF 220 indicates the H level (locked state) exceeds the length of the term during which the control signal latched in the FF 220 indicates the L level (unlock state) in a plurality of cycles of the frequency dividing CLK.

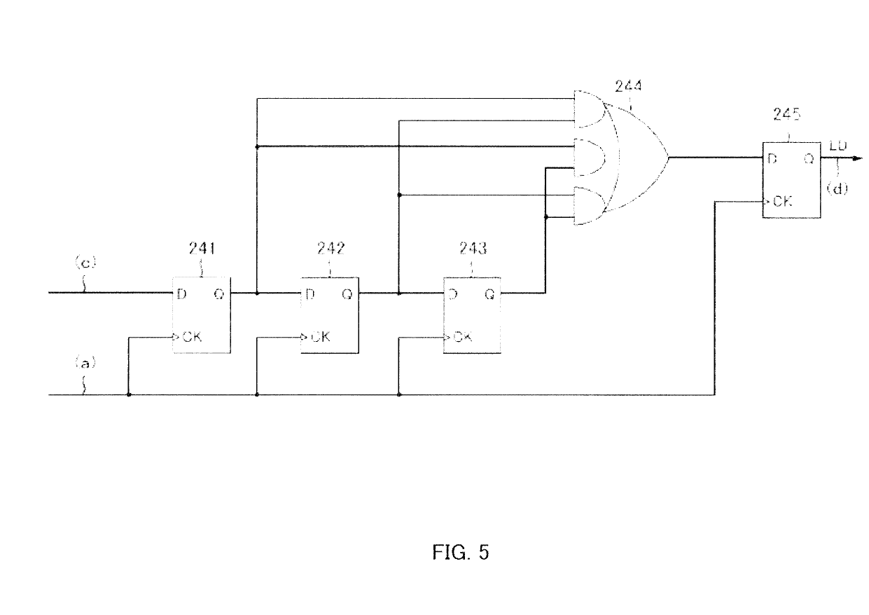

FIG. 5 is an exemplary circuit that realizes a decision-by-majority-scheme lock judging circuit 230. In FIG. 5, (a) denotes the frequency dividing CLK supplied to the lock judging circuit 230, (c) denotes the output of the FF 220, and (d) denotes the lock detecting signal LD.

The decision-by-majority-scheme lock judging circuit 230 consists of FFs 241, 242, 243, and 245 and an AND-OR element 244.

For the FF 241, the output of the FF 220 is inputted into the data input terminal thereof and the frequency dividing CLK is inputted into the clock input terminal thereof. Thereby, the FF 231 latches the output of the FF 220 in response to the rise of the frequency dividing CLK. Similarly, data latched in the FF 241 are shifted sequentially in response to the rise of the frequency dividing CLK to the FFs 242 and 243.

Representing an output of the FF 241 as “F(t−2)”, an output of the FF 242 as “F(t−1)”, and an output of the FF 243 as “F(t)”, an output of the AND-OR element 244 is represented as “F(t)×F(t−1)+F(t)×F(t−2)+F(t−1)×F(t−2)”. That is, the AND-OR element 244 outputs the H level when the data inputted into the FF 241 indicates the H level for a term of two cycles that is longer than 1.5 cycles (½ of three cycles) in three cycles of the frequency dividing CLK.

For the FF 245, the output of the AND-OR element 244 is inputted into a data input terminal thereof and the frequency dividing CLK is inputted into a clock input terminal thereof. Therefore, the FF 245 latches the output of the AND-OR element 244 in response to the rise of the frequency dividing CLK.

When the H level is latched in the FF 245, the PLL circuit is judged to be in the locked state. Therefore, in the locked state, a lock detecting signal LD outputted from the FF 245 is at the L level. In contrast, the PLL circuit is judged to be in an unlocked state when the L level is latched in the FF 245. Therefore, in the unlocked state, the lock detecting signal LD outputted from the FF 245 is at the L level.

In this manner, according to the decision-by-majority scheme, unlike the counter scheme, an appropriate judgment can be executed even when the term during which the locked/unlocked state is indicated is non-continuous in the predetermined judgment term. Compared to the counter scheme according to which the lock detecting signal LD is not determined until the term during which the locked state is indicated is counted for a term corresponding to the first term, according to the decision-by-majority scheme, the lock detecting signal LD is determined when the term during which the locked state is indicated for ½ of the predetermined judgment term is detected. Therefore, compared to the counter scheme, the time until the lock detecting signal LD is determined can be reduced according to decision-by-majority scheme.

<<Weighting Scheme>>

The lock judging circuit 230 according to an embodiment of the present invention can employ a weighting scheme. According to the weighting scheme, in a predetermined judgment term (for example, in 10 cycles), when the length of a term during which the locked state is indicated exceeds the length of a predetermined first term (for example, eight cycles), the lock detecting signal LD indicating to be in the locked state is outputted.

In FIG. 1, for example, a weighting-scheme lock judging circuit 230 is configured to output a lock detecting signal LD at the H level when the length of the term during which the control signal latched in the FF 220 indicates the H level (locked state) exceeds the length of a predetermined term for which the term thereof is set to be shorter than the predetermined term, in the predetermined judgment term.

Changing the viewpoint to FIG. 5, an exemplary circuit configuration that realizes the weighting-scheme lock judging circuit 230 will be described. That is, the lock judging circuit 230 shown in FIG. 5 outputs the lock detecting signal LD that indicates the locked state when a term during which the lock state is indicated continues for two cycles or more in three cycles of the frequency dividing CLK. Therefore, the lock judging circuit shown in FIG. 5 may be a so-called weighting-scheme lock judging circuit.

In this manner, according to the weighting scheme, similarly to the counter scheme, an appropriate judgment can be executed even when the term during which the locked/unlocked state is indicated is non-continuous in the predetermined judgment term. Compared to the counter scheme according to which the lock detecting signal LD is not determined until the term during which the locked state is indicated is counted for a term corresponding to the first term, according to the weighting scheme, the lock detecting signal LD is determined when the term during which the locked state is indicated for the first term which is set to be shorter than the predetermined judgment term is detected. Therefore, compared to the counter scheme and the decision-by-majority scheme, the length of time until the lock detecting signal LD is determined can be reduced according the weighting scheme.

Though the embodiments of the present invention have been described hereinabove, the above embodiments are for facilitating the understanding of the present invention and are not to be construed as limiting the present invention. The present invention may be varied or modified without departing from the spirit thereof and encompasses equivalents thereof.

What is claimed is:

1. A lock detecting circuit that detects whether a PLL circuit is in a locked state based on a phase difference signal supplied from a phase comparator of the PLL circuit, the lock detecting circuit comprising:
a first circuit that outputs a control signal having
one level when the phase difference signal does not indicate a generation of a phase difference, and
the other level when the phase difference signal indicates a generation of a phase difference;
a second circuit that latches the control signal; and
a third circuit that outputs, for a predetermined second term, a lock detecting signal indicating that the PLL circuit is in a locked state, when the latched control signal indicates the one level for a predetermined first term.

2. The lock detecting circuit of claim 1, wherein
the third circuit measures a term during which the latched control signal continuously indicates the one level and, when the measured term exceeds the predetermined first term in length, outputs the lock detecting signal.

3. The lock detecting circuit of claim 1, wherein
the second term is set to be a term during which the latched control signal indicates the one level.

4. The lock detecting circuit of claim 2, wherein
the third circuit executes the measurement based on a second clock signal phase-inverted from a first clock signal that is used for the latching in the second circuit.

5. The lock detecting circuit of claim 4, wherein
the first and the second clock signals are clock signals created from an identical clock source.

6. The lock detecting circuit of claim 1, wherein
the third circuit outputs the lock detecting signal when the length of the term during which the latched control signal indicates the one level exceeds the length of a term during which the latched control signal indicates the other level, in a predetermined judgment term.

7. The lock detecting circuit of claim 1, wherein
the third circuit outputs the lock detecting signal when the length of the term during which the latched control signal indicates the one level exceeds the length of the first term that is set to be shorter in length than a predetermined judgment term, in the predetermined judgment term.

8. A method for a lock detecting circuit to detect whether a PLL circuit is in a locked state based on a phase difference signal supplied from a phase comparator of the PLL circuit, the method comprising steps of:
creating a control signal that has one level when the phase difference signal does not indicate a generation of a phase difference, and that has the other level when the phase difference signal indicates a generation of a phase difference;
latching the control signal; and
outputting, for a predetermined second term, a lock detecting signal that indicates that the PLL circuit is in a locked state, when the latched control signal indicates the one level for a predetermined first term.
